(19) United States
(12) Patent Application Publication
(10) Pub. No.: US 2023/0154831 A1
(43) Pub. Date: May 18, 2023

(54) SEMICONDUCTOR STRUCTURE AND FORMING METHOD THEREOF

(71) Applicant: CHANGXIN MEMORY TECHNOLOGIES, INC., Hefei City (CN)

(72) Inventor: Yonghui ZHANG, Hefei City (CN)

(21) Appl. No.: 18/153,013

(22) Filed: Jan. 11, 2023

Related U.S. Application Data
(63) Continuation of application No. PCT/CN2021/131799, filed on Nov. 19, 2021.

(30) Foreign Application Priority Data
Aug. 30, 2021 (CN) 202111001404.9

(51) Int. Cl. H01L 23/48; H01L 21/768

(52) U.S. Cl. CPC H01L 23/481; H01L 21/76898; H01L 21/76804; H01L 21/76883; H01L 21/76844

(57) ABSTRACT

The present disclosure provides a semiconductor structure and a forming method thereof. The semiconductor structure includes: a substrate, including a first side and a second side opposite to each other; a dielectric layer, provided at the first side of the substrate; a first through silicon via (TSV) structure, extending from a top surface of the dielectric layer to the first side of the substrate; and a second TSV structure, extending from the second side of the substrate to the first side of the substrate, coming into contact with the first TSV structure at the first side of the substrate, and having a preset opening width.

### CROSS-REFERENCE TO RELATED APPLICATIONS

The present disclosure is a continuation application of International Patent Application No. PCT/CN2021/131799, filed on Nov. 19, 2021, which is based on and claims the priority to Chinese Patent Application No. 202111001404.9, titled “SEMICONDUCTOR STRUCTURE AND FORMING METHOD THEREOF” and filed on Aug. 30, 2021. The entire contents of International Patent Application No. PCT/CN2021/131799 and Chinese Patent Application No. 202111001404.9 are incorporated herein by reference.

### TECHNICAL FIELD

The present disclosure relates to, but is not limited to, a semiconductor structure and a forming method thereof.

### BACKGROUND

In the field of integrated circuits (ICs), according to the Moore's Law, the performance of ICs is increased exponentially with the doubling of semiconductor devices packaged in the ICs. In order to improve electrical performance of the ICs, there is an increasingly high level of integration in the ICs.

With development of the semiconductor field in recent years, applications of the Moore's Law in the semiconductor field are restricted. For the sake of effectiveness of the Moore's Law, improving performance of the ICs with the IC packaging technology is envisioned as one of key points to development of the semiconductor field.

The IC packaging technology means that a plurality of wafers are stacked and interconnected by through silicon vias (TSVs). Specifically, vertically interconnected TSV structures are separately formed on the plurality of wafers. Different wafers are electrically interconnected through a subsequent redistribution layer (RDL). The line width and yield of a TSV structure directly affect the size and electrical performance of a packaged structure.

### SUMMARY

A first aspect of the present disclosure provides a semiconductor structure, which includes:

a substrate, including a first side and a second side opposite to each other;

a dielectric layer, provided at the first side of the substrate;

a first TSV structure, extending from a top surface of the dielectric layer to the first side of the substrate; and

a second TSV structure, extending from the second side of the substrate to the first side of the substrate, coming into contact with the first TSV structure at the first side of the substrate, and having a preset opening width.

A second aspect of the present disclosure provides a forming method of a semiconductor structure, including:

providing a substrate and a dielectric layer disposed on the substrate, the substrate including a first side and a second side, and the dielectric layer being provided at the first side of the substrate;

forming a first TSV structure, the first TSV structure extending from a top surface of the dielectric layer to the first side of the substrate; and

forming a second TSV structure, the second TSV structure extending from the second side of the substrate to the first side of the substrate, coming into contact with the first TSV structure at the first side of the substrate, and having a preset opening width.

### BRIEF DESCRIPTION OF THE DRAWINGS

The accompanying drawings incorporated into the specification and constituting a part of the specification illustrate the embodiments of the present disclosure, and are used together with the description to explain the principles of the embodiments of the present disclosure. In these accompanying drawings, similar reference numerals represent similar elements. The accompanying drawings in the following description illustrate some rather than all of the embodiments of the present disclosure. Those skilled in the art may obtain other accompanying drawings based on these accompanying drawings without creative efforts.

FIG. 1 is a schematic structural view of a semiconductor structure according to an exemplary embodiment;

FIG. 2 illustrates projection of each of a first pattern and a second pattern of the semiconductor structure in FIG. 1 on a substrate;

FIG. 3 is a schematic structural view of a semiconductor structure according to an exemplary embodiment;

FIG. 4 illustrates projection of each of a first pattern, a second pattern and a metal liner of the semiconductor structure in FIG. 3 on a substrate;

FIG. 5 is a schematic structural view of a semiconductor structure according to an exemplary embodiment;

FIG. 6 illustrates projection of each of a first pattern and a metal liner of the semiconductor structure in FIG. 5 on a substrate;

FIG. 7 illustrates projection of each of a second pattern, a third pattern and a metal liner of the semiconductor structure in FIG. 5 on a substrate;

FIG. 8 is a flowchart of a forming method of a semiconductor structure according to an exemplary embodiment;

FIG. 9 is a flowchart for forming a first TSV structure in a forming method of a semiconductor structure according to an exemplary embodiment;

FIG. 10 is a flowchart for forming a second TSV structure in a forming method of a semiconductor structure according to an exemplary embodiment;

FIG. 11 is a flowchart of a forming method of a semiconductor structure according to an exemplary embodiment;

FIG. 12 is a flowchart of a forming method of a semiconductor structure according to an exemplary embodiment;

FIG. 13 is a flowchart of a forming method of a semiconductor structure according to an exemplary embodiment;

FIG. 14 is a schematic view for forming a first mask layer on a top surface of a dielectric layer in a forming method of a semiconductor structure according to an exemplary embodiment;

FIG. 15 is a schematic view for forming a first opening in a forming method of a semiconductor structure according to an exemplary embodiment;

FIG. 16 is a schematic view for forming a first barrier layer in a forming method of a semiconductor structure according to an exemplary embodiment;

FIG. 17 is a schematic view for forming a first TSV structure in a forming method of a semiconductor structure according to an exemplary embodiment;

FIG. 18 is a schematic view for performing first annealing in a forming method of a semiconductor structure according to an exemplary embodiment;

FIG. 19 is a schematic view for etching back a second side of a substrate in a forming method of a semiconductor structure according to an exemplary embodiment;

FIG. 20 is a schematic view for forming a second opening in a forming method of a semiconductor structure according to an exemplary embodiment;

FIG. 21 is a schematic view for forming a second barrier layer in a forming method of a semiconductor structure according to an exemplary embodiment;

FIG. 22 is a schematic view for performing second annealing in a forming method of a semiconductor structure according to an exemplary embodiment;

FIG. 23 is a schematic view for forming a first layer of dielectric structure in a forming method of a semiconductor structure according to an exemplary embodiment;

FIG. 24 is a schematic view for forming a trench in a first layer of dielectric structure in a forming method of a semiconductor structure according to an exemplary embodiment;

FIG. 25 is a schematic view for forming a metal liner in a forming method of a semiconductor structure according to an exemplary embodiment;

FIG. 26 is a schematic view for forming a first mask layer on a top surface of a dielectric layer in a forming method of a semiconductor structure according to an exemplary embodiment;

FIG. 27 is a schematic view for forming a first opening in a forming method of a semiconductor structure according to an exemplary embodiment;

FIG. 28 is a schematic view for forming a first TSV structure in a forming method of a semiconductor structure according to an exemplary embodiment;

FIG. 29 is a schematic view for forming a second opening in a forming method of a semiconductor structure according to an exemplary embodiment;

FIG. 30 is a schematic view for forming a second mask layer in a forming method of a semiconductor structure according to an exemplary embodiment;

FIG. 31 is a schematic view for forming a second opening and a third opening in a forming method of a semiconductor structure according to an exemplary embodiment;

FIG. 32 is a schematic view for forming a second barrier layer and a third barrier layer in a forming method of a semiconductor structure according to an exemplary embodiment; and

FIG. 33 is a schematic view for performing second annealing in a forming method of a semiconductor structure according to an exemplary embodiment.

### DETAILED DESCRIPTION

The technical solutions in the embodiments of the present disclosure are described below clearly and completely with reference to the accompanying drawings in the embodiments of the present disclosure. Apparently, the described embodiments are merely some rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

In an IC packaging technology, a plurality of wafers are stacked by forming TSV structures on the wafers, and the plurality of stacked wafers are interconnected by taking the TSV structures as leads.

With development of the semiconductor field, and particularly development of high bandwidth memories (HBMs), ICs tends to be gradually smaller, and sizes of the TSV structures directly affect miniaturization of the ICs.

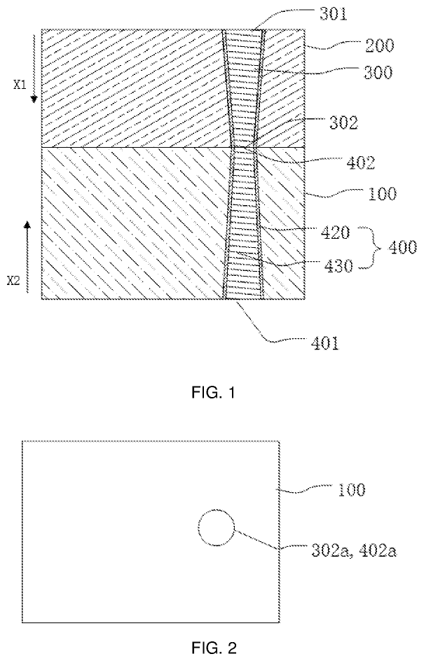

In view of this, an exemplary embodiment of the present disclosure provides a semiconductor structure, as shown in FIG. 1. FIG. 1 shows a structural view of a semiconductor structure according to an exemplary embodiment of the present disclosure. The semiconductor structure provided by the embodiment includes a substrate 100, a dielectric layer 200, a first TSV structure 300 in the dielectric layer 200, and a second TSV structure 400 in the substrate 100. The substrate 100 includes a first side and a second side opposite to each other. The dielectric layer 200 is provided at the first side of the substrate 100. The first TSV structure 300 extends from a top surface of the dielectric layer 200 to the first side of the substrate 100. The second TSV structure 400 extends from the second side of the substrate 100 to the first side of the substrate 100. The second TSV structure 400 comes into contact with the first TSV structure 300 at the first side of the substrate 100. The second TSV structure 400 has a preset opening width.

The substrate 100 may include a semiconductor material. The semiconductor material may be one or more selected from the group consisting of silicon, germanium, a silicon-germanium compound, and a silicon-carbon compound. Exemplarily, the substrate 100 may be a silicon-on-insulator (SOI) substrate or a germanium-on-insulator (GOI) substrate.

The dielectric layer 200 is a semiconductor device layer at the first side of the substrate 100. The dielectric layer 200 includes a dielectric material and one or more semiconductor devices. The semiconductor device in the dielectric layer 200 may be a gate, a source and a drain of a transistor or another semiconductor device or the like. The dielectric material in the dielectric layer 200 may be silicon dioxide, silicon nitride, or a combination thereof.

As shown in FIG. 1, the first TSV structure 300 extends from the top surface of the dielectric layer 200 to the first side of the substrate 100. The second TSV structure 400 extends from the second side of the substrate 100 to the first side of the substrate 100. The first TSV structure 300 and the second TSV structure 400 that extend reversely come into contact at the first side of the substrate 100. In the embodiment, the contact formed by the first TSV structure 300 and the second TSV structure 400 is an electrical connection. For example, the first TSV structure 300 and the second TSV structure 400 may contact directly to form the electrical connection or form the electrical connection through a conductive connecting piece.

A two-segment structure including the first TSV structure 300 and the second TSV structure 400 is provided in the semiconductor structure. The first TSV structure 300 and the second TSV structure 400 that are provided reversely form an electrical connection structure penetrating through the semiconductor structure. Therefore, the semiconductor structure in the embodiment shortens manufacturing lengths of the first TSV structure 300 and the second TSV structure 400, and correspondingly reduces a size of the first TSV structure 300 on the top surface of the dielectric layer 200 and a size of the second TSV structure 400 at the second side of the substrate 100, thereby achieving the smaller semiconductor structure overall.

As an exemplary embodiment of the present disclosure, most contents in the embodiment are the same as those in the foregoing embodiment. The embodiment differs from the foregoing embodiment in: As shown in FIG. 2, referring to FIG. 1, the first TSV structure 300 defines a first pattern 302a at a bottom surface of the dielectric layer 200. The second TSV structure 400 defines a second pattern 402a at the first side of the substrate 100. Projection of the first pattern 302a on the substrate 100 coincides with projection of the second pattern 402a on the substrate 100.

In the embodiment, the first TSV structure 300 and the second TSV structure 400 are aligned. Specifically, a bottom 302 of the first TSV structure 300 and a bottom 402 of the second TSV structure 400 are aligned at a junction surface between the substrate 100 and the dielectric layer 200. Since the first TSV structure 300 and the second TSV structure 400 contact directly at the first side of the substrate 100, the contact resistance between the first TSV structure 300 and the second TSV structure 400 is minimized.

As an exemplary embodiment of the present disclosure, most contents in the embodiment are the same as those in the foregoing embodiment. The embodiment differs from the foregoing embodiment in: As shown in FIG. 1, an extension direction of the first TSV structure 300 serves as a first direction (namely the X1 direction in FIG. 1). The first direction refers to an axial direction of the first TSV structure 300. Along the first direction, a radial size of the first TSV structure 300 decreases gradually. The top 301 serves as a maximum section of the first TSV structure 300 in a radial direction, and the bottom 302 serves as a minimum section. It is to be noted that the maximum section used herein refers to a section having a maximum sectional area, and the minimum section refers to a section having a minimum sectional area.

An extension direction of the second TSV structure 400 serves as a second direction opposite to the first direction (namely the X2 direction in FIG. 1). The second direction refers to an axial direction of the second TSV structure 400. Along the first direction, a radial size of the second TSV structure 400 decreases gradually. The top 401 serves as a maximum section of the second TSV structure 400 in a radial direction, and the bottom 402 serves as a minimum section.

The bottom 302 of the first TSV structure 300 and the bottom 402 of the second TSV structure 400 come into contact at the first side of the substrate 100. In the embodiment, the minimum sections of the first TSV structure 300 and the second TSV structure 400 in the radial direction are located at the first side of the substrate 100, which shortens manufacturing lengths of the first TSV structure 300 and the second TSV structure 400, and reduces sizes of the first TSV structure 300 and the second TSV structure 400.

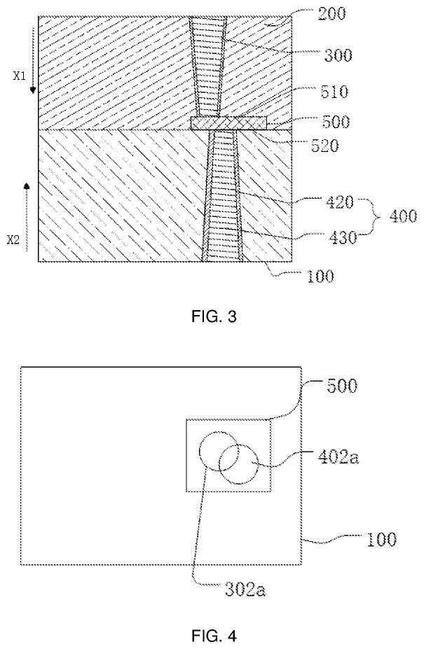

As an exemplary embodiment of the present disclosure, most contents in the embodiment are the same as those in the foregoing embodiment. The embodiment differs from the foregoing embodiment in: As shown in FIG. 3, a metal liner 500 is provided in the dielectric layer 200. Both the first TSV structure 300 and the second TSV structure 400 come into contact with the metal liner 500.

As shown in FIG. 3, referring to FIG. 1, a first side of the metal liner 500 close to the substrate 100 is provided in the dielectric layer 200. The metal liner 500 includes the first side 510 and a second side 520. The first side 510 of the metal liner 500 faces toward the top surface of the dielectric layer 200, while the second side 520 of the metal liner 500 faces toward the substrate 100. The bottom 302 of the first TSV structure 300 and the first side 510 of the metal liner 500 come into contact to form an electrical connection, and the bottom 402 of the second TSV structure 400 and the second side 520 of the metal liner 500 come into contact to form an electrical connection. The first TSV structure 300 is electrically connected to the second TSV structure 400 through the metal liner 500. A material of the metal liner 500 may include a conductive metal material such as copper, aluminum, silver, nickel or alloy thereof.

As shown in FIG. 4, the first TSV structure 300 defines a first pattern 302a at a bottom surface of the dielectric layer 200. Projection of the first pattern 302a on the substrate 100 falls within projection of the metal liner 500 on the substrate 100. The second TSV structure 400 defines a second pattern 402a at the first side of the substrate 100. Projection of the second pattern 402a on the substrate 100 falls within the projection of the metal liner 500 on the substrate 100. In the embodiment, the projection of the first pattern 302a on the substrate 100 may overlap partially with the projection of the second pattern 402a on the substrate 100.

When the first TSV structure 300 and the second TSV structure 400 are directly aligned for connection, high requirements are imposed on accuracy of alignment. Even in the case of a tiny alignment error, electrical performance of the semiconductor structure will be greatly affected. In order to achieve better electrical performance in the embodiment, the metal liner 500 is provided in the dielectric layer 200, and the first TSV structure 300 is electrically connected to the second TSV structure 400 through the metal liner 500. While providing a larger contact area, the metal liner 500 can meet the electrical conductivity of the semiconductor structure. Moreover, by virtue of a thickness of the metal liner 500 in the first direction (the X1 direction in FIG. 1), the manufacturing length of the first TSV structure 300 can further be shortened, and the area of the top 301 of the first TSV structure 300 can further be reduced.

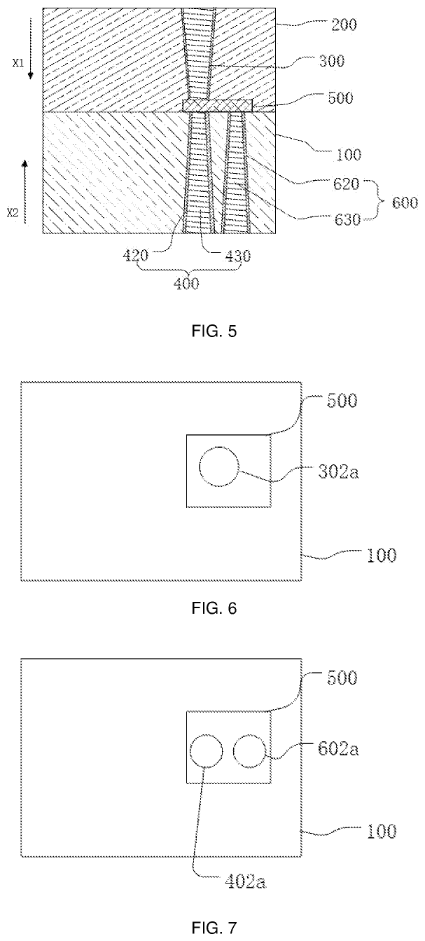

As an exemplary embodiment of the present disclosure, most contents in the embodiment are the same as those in the foregoing embodiment. The embodiment differs from the foregoing embodiment in: As shown in FIG. 5, the semiconductor structure further includes a third TSV structure 600. The third TSV structure 600 extends from the second side of the substrate 100 to the first side of the substrate 100. The third TSV structure 600 is connected to the metal liner 500.

Exemplarily, the second TSV structure 400 has a preset opening width of 2 μm to 20 μm in the embodiment. The third TSV structure 600 has a preset opening width of for example 2 μm to 20 μm, which may be the same as that of the second TSV structure, and certainly may also be different from that of the second TSV structure. For example, when the second TSV structure 400 and the third TSV structure 600 have a same preset opening width, namely the second TSV structure 400 has the preset opening width of 10 μm, and the third TSV structure 600 has the preset opening width of 10 μm, the best electrical conductivity is achieved by connecting the third TSV structure 600 and the second TSV structure 400 in parallel.

As shown in FIG. 6, the first TSV structure 300 defines a first pattern 302a at a bottom surface of the dielectric layer 200. Projection of the first pattern 302a on the substrate 100 falls within projection of the metal liner 500 on the substrate 100. As shown in FIG. 7, the second TSV structure 400 defines a second pattern 402a at the first side of the substrate 100. The third TSV structure 600 defines a third pattern 602a at the first side of the substrate 100. Projection of each of the second pattern 402a and the third pattern 602a on the substrate 100 falls within the projection of the metal liner 500 on the substrate 100. In the embodiment, the projection of the first pattern 302a on the substrate 100 may overlap partially with the projection of the second pattern 402a on the substrate 100. Alternatively, the projection of the first pattern 302a on the substrate 100 may overlap partially with the projection of the third pattern 602a on the substrate 100.

As shown in FIG. 5 in the embodiment, by connecting the third TSV structure 600 and the second TSV structure 400 in parallel, the connecting area with the second side 520 (shown in FIG. 3) of the metal liner 500 is increased. Consequently, the opening widths of the third TSV structure 600 and the second TSV structure 400 can be reduced, and the lengths of the third TSV structure 600 and the second TSV structure 400 can also be shortened correspondingly, thereby reducing the thickness required by the substrate 100.

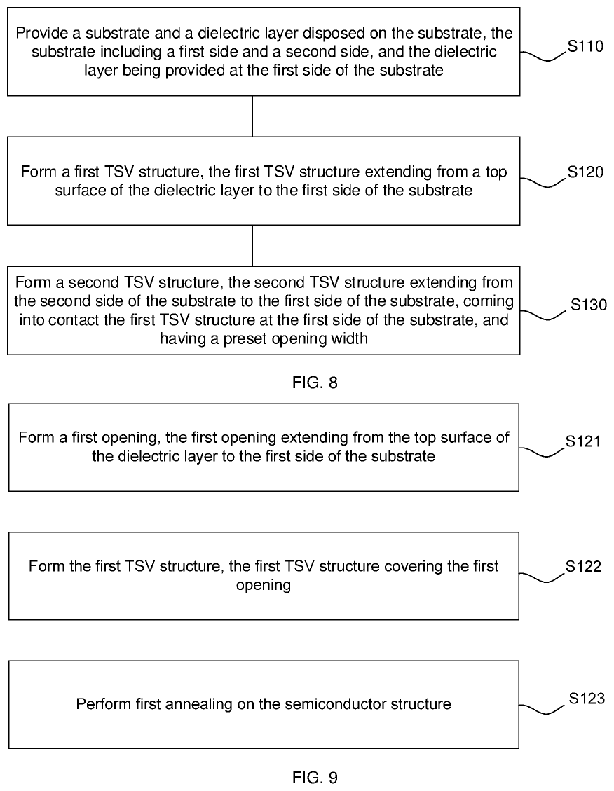

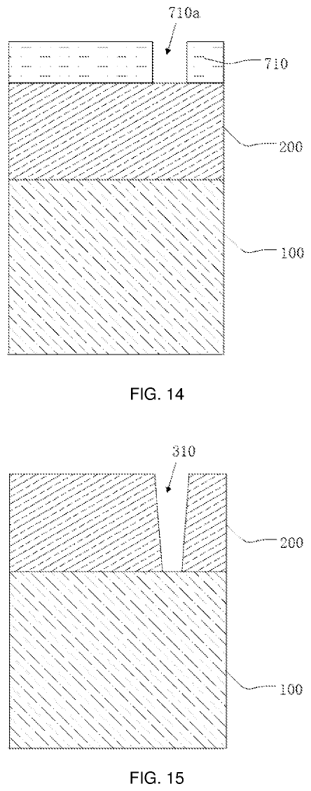

An exemplary embodiment of the present disclosure provides a forming method of a semiconductor structure, as shown in FIG. 8. FIG. 8 is a flowchart of a forming method of a semiconductor structure according to an exemplary embodiment of the present disclosure. FIG. 14 to FIG. 22 are schematic views in various stages of the forming method of a semiconductor structure. The forming method of a semiconductor structure is described below with reference to FIG. 14 to FIG. 22.

The semiconductor structure is not limited in the embodiment. The semiconductor structure is described below by taking a dynamic random access memory (DRAM) as an example, but the embodiment is not limited thereto. The semiconductor structure in the embodiment may also be other structures.

As shown in FIG. 8, the forming method of a semiconductor structure provided by the exemplary embodiment of the present disclosure includes the following steps:

S110: Provide a substrate and a dielectric layer disposed on the substrate, the substrate including a first side and a second side, and the dielectric layer being provided at the first side of the substrate.

As shown in FIG. 1, the substrate 100 may include a semiconductor material. The semiconductor material may be one or more selected from the group consisting of silicon, germanium, a silicon-germanium compound, and a silicon-carbon compound. Exemplarily, the substrate 100 may be an SOI substrate or a GOI substrate.

The dielectric layer 200 may be formed by depositing a dielectric material at the first side of the substrate 100 through chemical vapor deposition (CVD) or physical vapor deposition (PVD). The dielectric layer 200 may be of a single-layer or laminated structure. Each layer of structure in the dielectric layer 200 may be provided therein with one or more semiconductor devices. The semiconductor device may be a gate, a source and a drain of a transistor or another semiconductor device or the like. The dielectric material in the dielectric layer 200 may be silicon dioxide, silicon nitride, or a combination thereof.

S120: Form a first TSV structure, the first TSV structure extending from a top surface of the dielectric layer to the first side of the substrate.

As shown in FIG. 17, an extension direction of the first TSV structure 300 serves as a first direction (namely the X1 direction in FIG. 17).

S130: Form a second TSV structure, the second TSV structure extending from the second side of the substrate to the first side of the substrate, coming into contact the first TSV structure at the first side of the substrate, and having a preset opening width.

Referring to FIG. 1, the second TSV structure 400 extends in a second direction (the X2 direction in FIG. 1) opposite to the first direction (the X1 direction in FIG. 1).

Referring to FIG. 1, the bottom 302 of the first TSV structure 300 and the bottom 402 of the second TSV structure 400 come into contact at the first side of the substrate 100. The contact between the bottom 302 of the first TSV structure 300 and the bottom 402 of the second TSV structure 400 may be an electrical connection. They may contact directly to form the electrical connection, and may also be connected indirectly through other conductive elements to form the electrical connection.

In the embodiment, the first TSV structure and the second TSV structure are connected to form an electrical connection structure penetrating through the semiconductor structure, which shortens manufacturing lengths of the first TSV structure and the second TSV structure, and correspondingly reduces an area of the first TSV structure on the top surface of the dielectric layer and an area of the second TSV structure at the second side of the substrate, thereby achieving the smaller semiconductor structure.

According to an exemplary embodiment of the present disclosure, the embodiment is a description on Step S120 in the foregoing embodiment.

As shown in FIG. 9, the forming a first TSV structure includes:

S121: Form a first opening, the first opening extending from the top surface of the dielectric layer to the first side of the substrate.

As shown in FIG. 14, a first mask layer 710 is formed on the top surface of the dielectric layer 200. The first mask layer 710 includes a first pattern 710a. The first pattern 710a exposes a part of the top surface of the dielectric layer 200. As shown FIG. 15, referring to FIG. 14, dry or wet etching is performed on the dielectric layer 200 according to the first pattern 710a, until the first side of the substrate 100 is exposed, thereby forming the first opening 310. Under the influence of the etching process, a radial size of the first opening 310 decreases gradually in the first direction (namely the X1 direction in FIG. 1) from the top surface of the dielectric layer 200 to the first side of the substrate 100. The first opening 310 has an inverted trapezoidal structure in the first direction.

S122: Form the first TSV structure, the first TSV structure covering the first opening.

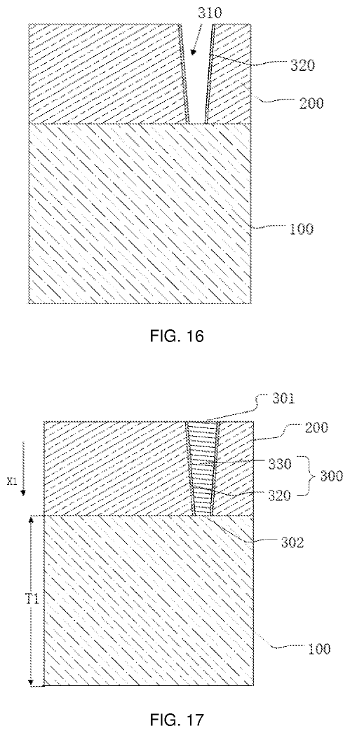

As shown in FIG. 16, referring to FIG. 15, a barrier material may be deposited by atomic layer deposition (ALD). The barrier material covers a sidewall of the first opening 310 to form a first barrier structure 320. As shown in FIG. 17, referring to FIG. 16, a conductive material is deposited by the ALD to fill the first opening 310, thereby forming a first conductive structure 330. The first barrier structure 320 and the first conductive structure 330 form the first TSV structure 300.

Exemplarily, the barrier material may be titanium, titanium nitride, tantalum, or tantalum-nitride. In the embodiment, the barrier material is titanium nitride.

The conductive material may be one or more selected from the group consisting of aluminum, copper, aluminum-copper and polysilicon. In the embodiment, the conductive material is copper metal.

S123: Perform first annealing on the semiconductor structure.

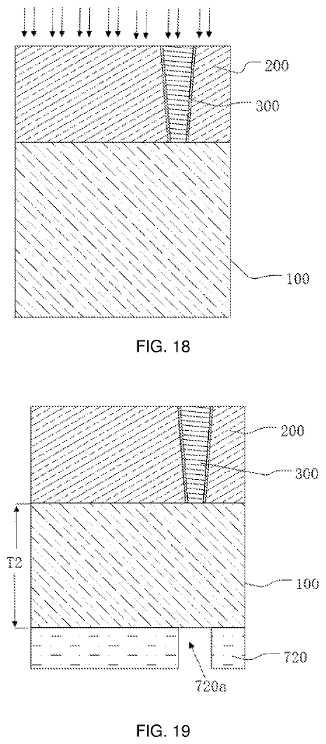

As shown in FIG. 18, upon formation of the first TSV structure 300, the first annealing is performed on the semiconductor structure. Specifically, the semiconductor structure is subjected to thermal anneal at a temperature of at least 400° C. for 30 min or more, such that lattices of a first conductive structure 330 become more uniform and complete, thereby reducing micro voids during filling of the conductive material, and improving the electrical performance of the first TSV structure 300.

As shown in FIG. 17 and FIG. 18, the first direction refers to an axial direction of the first TSV structure 300. Along the first direction, a radial size of the first TSV structure 300 decreases gradually. The top 301 serves as a maximum section of the first TSV structure 300 in a radial direction, and the bottom 302 serves as a minimum section.

In the embodiment, the manufacturing length of the first TSV structure 300 is the length of the dielectric layer 200 in the first direction, which shortens the manufacturing length of the first TSV structure 300, reduces an area of the top surface of the first TSV structure 300, and achieves the smaller first TSV structure 300.

According to an exemplary embodiment of the present disclosure, the embodiment is a description on Step S130 in the foregoing embodiment.

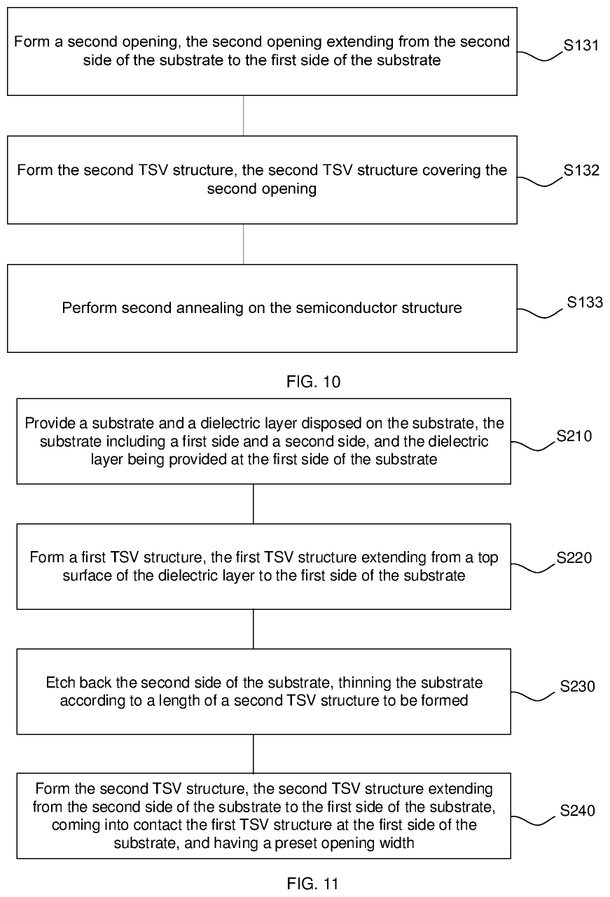

As shown in FIG. 10, the forming a second TSV structure includes:

S131: Form a second opening, the second opening extending from the second side of the substrate to the first side of the substrate.

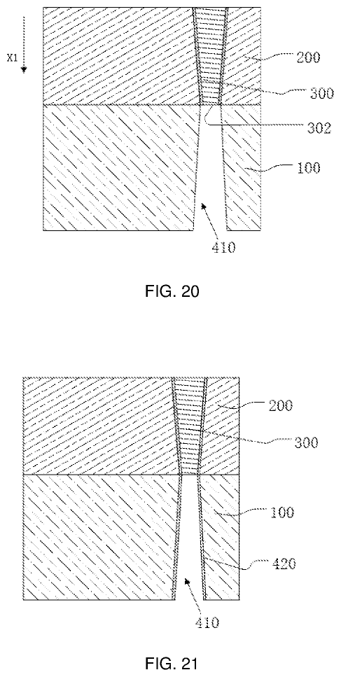

As shown in FIG. 19, a second mask layer 720 is formed at the second side of the substrate 100. The second mask layer 720 includes a second pattern 720a. The second pattern 720a exposes a part of the second side of the substrate 100. As shown FIG. 20, referring to FIG. 19, dry or wet etching is performed on the substrate 100 according to the second pattern 720a, until the bottom 302 of the first TSV structure 300 is exposed, thereby forming the second opening 410. The second opening 410 extends along the second direction (namely the X2 direction in FIG. 1). The second direction is opposite to the first direction. Under the influence of the etching process, a radial size of the second opening 410 decreases gradually in the second direction from the second side of the substrate 100 to the first side of the substrate 100. The second opening 410 has a trapezoidal structure in the second direction.

S132: Form the second TSV structure, the second TSV structure covering the second opening.

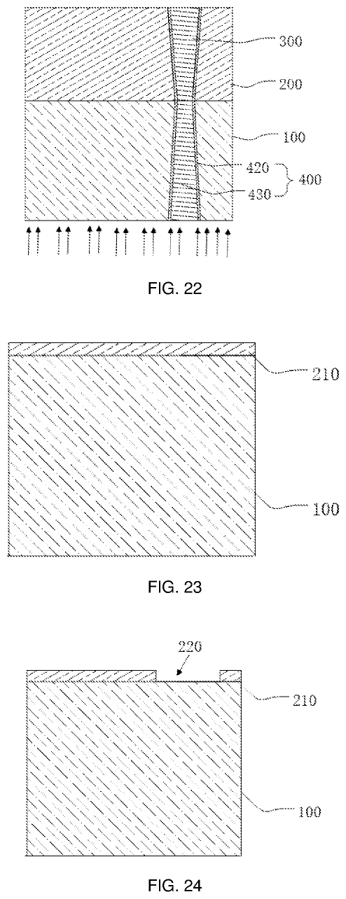

The process of forming the second TSV structure 400 is the same as that of forming the first TSV structure 300. As shown in FIG. 21, referring to FIG. 20, a barrier material is deposited to form a second barrier structure 420. Referring to FIG. 21 and FIG. 22, a conductive material is deposited to fill the second opening 410, thereby forming a second conductive structure 430. The second barrier structure 420 and the second conductive structure 430 form the second TSV structure 400.

S133: Perform second annealing on the semiconductor structure.

As shown in FIG. 22, upon formation of the second TSV structure 400, the second annealing is performed on the semiconductor structure. Specifically, the semiconductor structure is subjected to thermal anneal at a temperature of at least 400° C. for 30 min or more, and thus is more stable.

Referring to FIG. 1, the second direction refers to an axial direction of the second TSV structure 400. Along the axial direction, a radial size of the second TSV structure 400 decreases gradually. The top 401 serves as a maximum section of the second TSV structure 400 in a radial direction, and the bottom 402 serves as a minimum section.

According to the semiconductor structure formed in the embodiment, the minimum sections of the first TSV structure 300 and the second TSV structure 400 in the radial direction are located at the first side of the substrate 100, which shortens manufacturing lengths of the first TSV structure 300 and the second TSV structure 400, and reduces sizes of the first TSV structure 300 and the second TSV structure 400.

Referring to FIG. 2, the first TSV structure 300 defines a first pattern 302a at a bottom surface of the dielectric layer 200. The second TSV structure 400 defines a second pattern 402a at the first side of the substrate 100. Projection of the first pattern 302a on the substrate 100 coincides with projection of the second pattern 402a on the substrate 100. In the embodiment, the first TSV structure 300 and the second TSV structure 400 are aligned. Specifically, a bottom 302 of the first TSV structure 300 and a bottom 402 of the second TSV structure 400 are aligned at a junction surface between the substrate 100 and the dielectric layer 200. Since the first TSV structure 300 and the second TSV structure 400 directly come into contact at the first side of the substrate 100, the contact resistance between the first TSV structure 300 and the second TSV structure 400 is minimized.

Moreover, the first TSV structure and the second TSV structure are manufactured in two times. In contrast to a solution in which a TSV structure is formed in a substrate and a dielectric layer in a penetrating manner, the forming method in the embodiment has less filling of the conductive material in the manufacture. Upon formation of the first TSV structure and the second TSV structure, the annealing is performed, such that the first TSV structure and the second TSV structure are treated well to avoid insufficient annealing of the thermal treatment process on the conductive material due to large length and size of the TSV and excessive filling of the conductive material. By annealing the semiconductor structure repeatedly, the forming method in the embodiment makes lattices in the conductive material more uniform, and improves the conducting stability of the semiconductor structure.

An exemplary embodiment of the present disclosure provides a forming method of a semiconductor structure, as shown in FIG. 11. FIG. 11 is a flowchart of a forming method of a semiconductor structure according to an exemplary embodiment of the present disclosure.

As shown in FIG. 11, the forming method of a semiconductor structure provided by the exemplary embodiment of the present disclosure includes the following steps:

S210: Provide a substrate and a dielectric layer disposed on the substrate, the substrate including a first side and a second side, and the dielectric layer being provided at the first side of the substrate.

S220: Form a first TSV structure, the first TSV structure extending from a top surface of the dielectric layer to the first side of the substrate.

S230: Etch back the second side of the substrate, thereby thinning the substrate according to a length of a second TSV structure to be formed.

Referring to FIG. 2, a bottom surface of the first TSV structure 300 defines a first pattern 302a at the first side of the substrate 100. In order that the subsequently formed second TSV structure 400 can contact the first TSV structure 300 well at the first side of the substrate 100, an area of a second pattern 402a formed by the second TSV structure 400 at the first side of the substrate 100 is approximately the same as that of the first pattern 302a, and projection of the second pattern 402a on the substrate 100 can cover projection of the first pattern 302a on the substrate 100.

In the embodiment, as shown in FIG. 17, the initial thickness of the substrate 100 serves as a first thickness T1. Referring to FIG. 2 and FIG. 19, a minimum manufacturing length of the second TSV structure 400 to be formed is obtained according to the area of the second pattern 402a to be formed and an etching rate of an etching process for forming the second TSV structure 400 on the substrate 100. As shown in FIG. 19, referring to FIG. 17, the second side of the substrate 100 is etched back according to the minimum manufacturing length of the second TSV structure 400 to be formed, thereby thinning the substrate 100 to a second thickness T2.

S240: Form the second TSV structure, the second TSV structure extending from the second side of the substrate to the first side of the substrate, coming into contact the first TSV structure at the first side of the substrate, and having a preset opening width.

Steps S210 and S220 in the embodiment are implemented in the same manner as Steps S110 and S120 of the foregoing embodiment, and will not be repeated herein. Step S240 of the embodiment is implemented in the same manner as Step S130 of the foregoing embodiment, and will not be repeated herein.

In the embodiment, the substrate is thinned according to the length of the second TSV structure to be formed, such that the semiconductor structure is thinner and smaller. The forming method in the embodiment achieves the smaller semiconductor structure overall, reduces influences of the TSV structure on the size of the semiconductor structure, and taps the potential of the semiconductor structure toward further miniaturization.

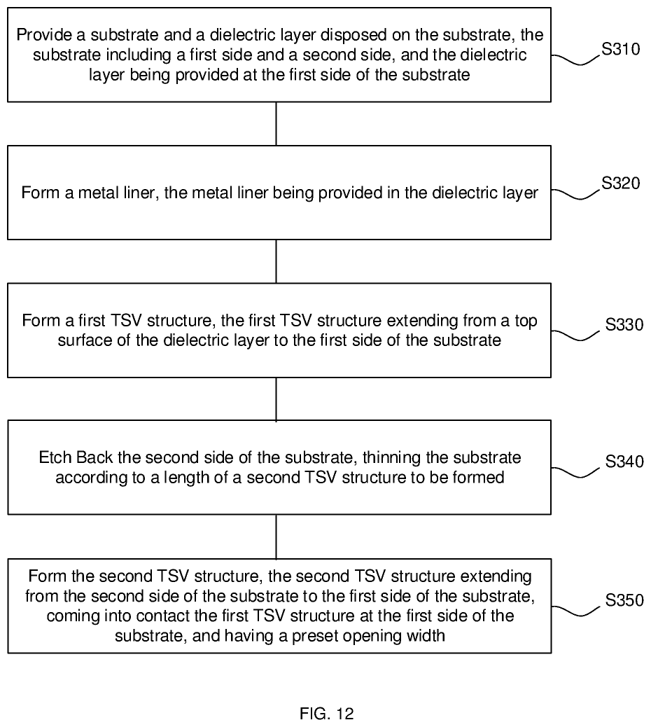

An exemplary embodiment of the present disclosure provides a forming method of a semiconductor structure, as shown in FIG. 12. FIG. 12 is a flowchart of a forming method of a semiconductor structure according to an exemplary embodiment of the present disclosure.

As shown in FIG. 12, the forming method of a semiconductor structure provided by the exemplary embodiment of the present disclosure includes the following steps:

S310: Provide a substrate and a dielectric layer disposed on the substrate, the substrate including a first side and a second side, and the dielectric layer being provided at the first side of the substrate.

S320: Form a metal liner, the metal liner being provided in the dielectric layer.

In the embodiment, Step S320 of forming a metal liner 500 and Step S310 of providing a dielectric layer 200 on the substrate 100 are performed at the same time.

In the embodiment, the dielectric layer 200 includes at least a single layer of dielectric structure. As shown in FIG. 23, a dielectric material is deposited at the first side of the substrate 100 to form a first layer of dielectric structure 210. As shown in FIG. 24, a trench 220 is formed in the first layer of dielectric structure 210. The trench 220 exposes a part of the substrate 100. As shown in 25, the metal liner 500 is provided in the trench 220. The dielectric material is continuously deposited to form the dielectric layer 200. As shown in FIG. 26, the finally formed dielectric layer 200 includes the metal liner 500.

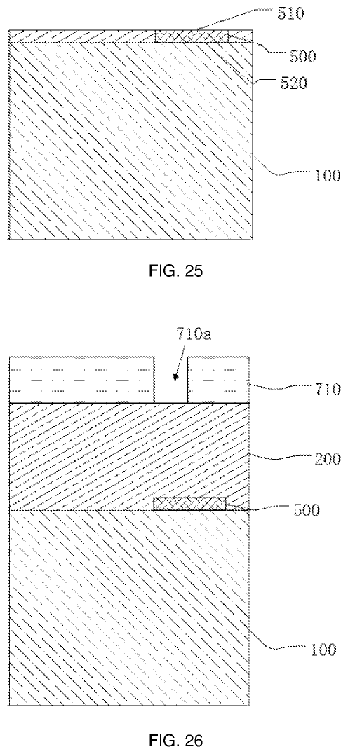

As shown in FIG. 25, referring to FIG. 26, the metal liner 500 includes a first side 510 facing toward the top surface of the dielectric layer 200, and a second side 520 facing toward the substrate 100.

S330: Form a first TSV structure, the first TSV structure extending from a top surface of the dielectric layer to the first side of the substrate.

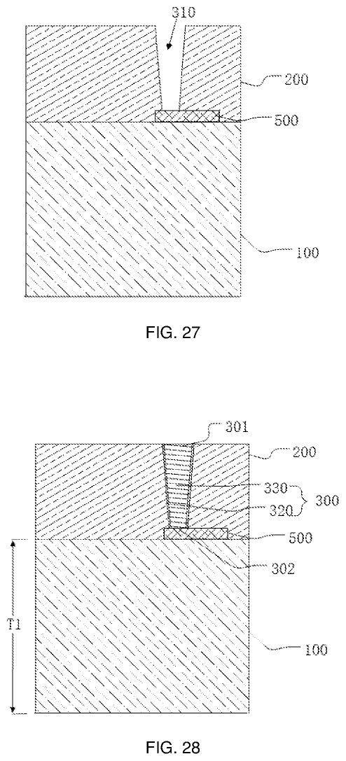

As shown in FIG. 27, referring to FIG. 25, while the first TSV structure 300 is formed, the first side 510 of the metal liner 500 is taken as an etching stop surface. The etching is performed until the first side 510 of the metal liner 500 is exposed, thereby forming a first opening 310. As shown in FIG. 28, the formed first TSV structure 300 is connected to the first side 510 (referring to FIG. 3) of the metal liner 500.

S340: Etch back the second side of the substrate, thereby thinning the substrate according to a length of a second TSV structure to be formed.

S350: Form the second TSV structure, the second TSV structure extending from the second side of the substrate to the first side of the substrate, coming into contact the first TSV structure at the first side of the substrate, and having a preset opening width.

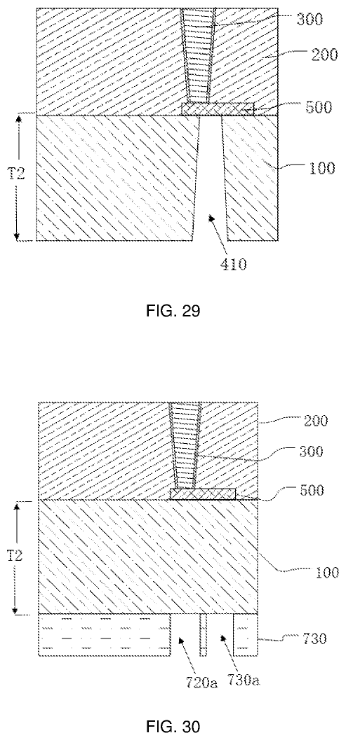

As shown in FIG. 29, referring to FIG. 25, while the second TSV structure 400 is formed, the second side 520 of the metal liner 500 is taken as an etching stop surface. The etching is performed until the second side 520 of the metal liner 500 is exposed, thereby forming a second opening 410. As shown in FIG. 3, the formed second TSV structure 400 is connected to the second side 520 of the metal liner 500.

Referring to FIG. 4, the first TSV structure 300 defines a first pattern 302a at a bottom surface of the dielectric layer 200. Projection of the first pattern 302a on the substrate 100 falls within projection of the metal liner 500 on the substrate 100. The second TSV structure 400 defines a second pattern 402a at the first side of the substrate 100. Projection of the second pattern 402a on the substrate 100 falls within the projection of the metal liner 500 on the substrate 100. In the embodiment, referring to FIG. 4, the projection of the first pattern 302a on the substrate 100 overlaps partially with the projection of the second pattern 402a on the substrate 100.

In the embodiment, the first TSV structure and the second TSV structure connected by the metal liner, which reduces the requirement on accuracy of the position of the formed second TSV structure. Even though the second TSV structure is positionally deviated from the first TSV structure, desirable electrical contact between the second TSV structure and the first TSV structure can still be ensured. Moreover, by providing the metal liner in the dielectric layer, the manufacturing length of the first TSV structure is further shortened, and the size of the first TSV structure on the top surface of the dielectric layer can further be reduced.

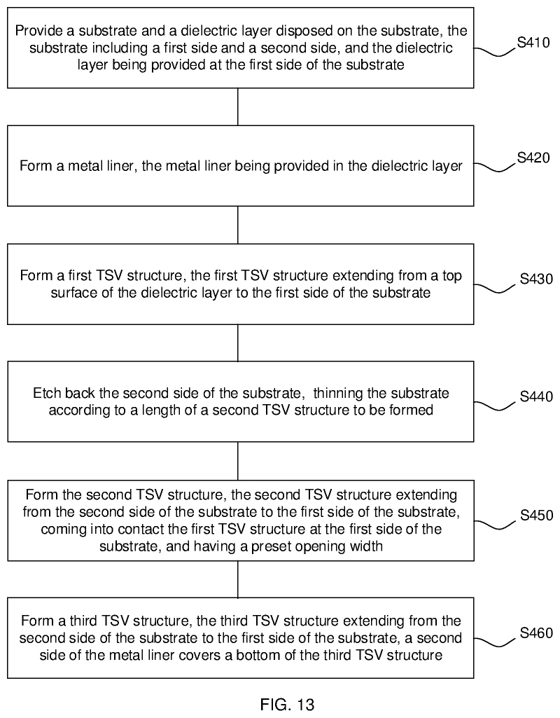

An exemplary embodiment of the present disclosure provides a forming method of a semiconductor structure, as shown in FIG. 13. FIG. 13 is a flowchart of a forming method of a semiconductor structure according to an exemplary embodiment of the present disclosure.

As shown in FIG. 13, the forming method of a semiconductor structure provided by the exemplary embodiment of the present disclosure includes the following steps:

S410: Provide a substrate and a dielectric layer disposed on the substrate, the substrate including a first side and a second side, and the dielectric layer being provided at the first side of the substrate.

S420: Form a metal liner, the metal liner being provided in the dielectric layer.

S430: Form a first TSV structure, the first TSV structure extending from a top surface of the dielectric layer to the first side of the substrate.

S440: Etch back the second side of the substrate, thereby thinning the substrate according to a length of a second TSV structure to be formed.

S450: Form the second TSV structure, the second TSV structure extending from the second side of the substrate to the first side of the substrate, coming into contact the first TSV structure at the first side of the substrate, and having a preset opening width.

S460: Form a third TSV structure, the third TSV structure extending from the second side of the substrate to the first side of the substrate, and a second side of the metal liner covering a bottom surface of the third TSV structure.

Steps S410 to S450 in the embodiment are implemented in the same manner as Steps S310 to S350 of the foregoing embodiment, and will not be repeated herein.

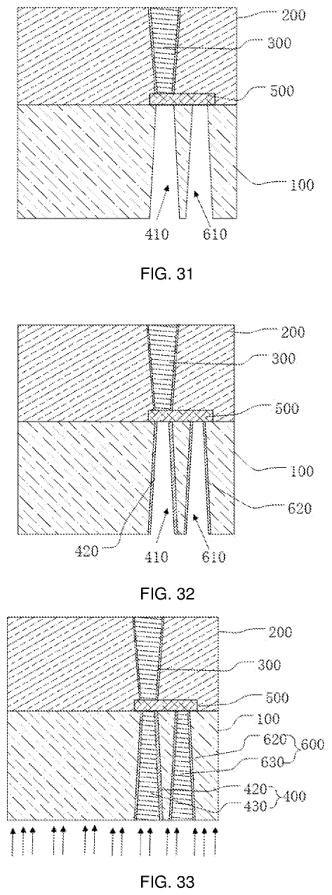

Step S460 of forming a third TSV structure includes: Form a third opening 610, the third opening 610 extending from the second side of the substrate 100 to the first side of the substrate 100, and exposing a part of the second side 520 (shown in FIG. 25) of the metal liner 500, as shown in FIG. 31. As shown in FIG. 32, a barrier material is deposited to cover a sidewall of the third opening 610, thereby forming a third barrier structure 620. As shown in FIG. 33, referring to FIG. 32, a conductive material is deposited to fill the third opening 610, thereby forming a third conductive structure 630. The third barrier structure 620 and the third conductive structure 630 form the third TSV structure 600. The third TSV structure 600 covers the third opening 610 and the exposed second side 520 (shown in FIG. 25) of the metal liner 500.

In the embodiment, Step S450 and Step S460 can be performed at the same time. In Step S440, the second side of the substrate 100 is etched back to thin the substrate 100 to a thickness T2. As shown in FIG. 30, a second mask layer 730 is formed at the second side of the substrate 100. The second mask layer 730 includes a second pattern 720a and a third pattern 730a. As shown in FIG. 31, referring to FIG. 30, the substrate 100 is etched according to the second pattern 720a and the third pattern 730a to form a second opening 410 and a third opening 610. As shown in FIG. 33, the second TSV structure 400 is provided in the second opening 410, and the third TSV structure 600 is provided in the third opening 610. Second annealing is performed on the semiconductor structure. With repeated annealing, the first TSV structure 300 and the second TSV structure 400 are annealed more completely to improve the thermostability.

As shown in FIG. 5, referring to FIG. 6, the first TSV structure 300 defines a first pattern 302a at a bottom surface of the dielectric layer 200. Projection of the first pattern 302a on the substrate 100 falls within projection of the first side 510 of the metal liner 500 on the substrate 100. As shown in FIG. 7, the second TSV structure 400 defines a second pattern 402a at the first side of the substrate 100. The third TSV structure 600 defines a third pattern 602a at the first side of the substrate 100. Projection of each of the second pattern 402a and the third pattern 602a on the substrate 100 falls within projection of the second side 520 of the metal liner 500 on the substrate 100.

In the embodiment, the formed third TSV structure 600 is connected to the second TSV structure 400 in parallel, and may, for example, have a same preset width as the second TSV structure 400, which increases a contact area with the second side 520 of the metal liner 500. Consequently, sizes of the third TSV structure 600 and the second TSV structure 400 can be further reduced, manufacturing lengths of the third TSV structure 600 and the second TSV structure 400 can also be shortened correspondingly, and thus a thickness required by the substrate 100 is reduced. While the second side of the substrate 100 is thinned, the substrate 100 can be removed more to achieve the smaller semiconductor structure.

According to the forming method of a semiconductor structure provided by the present disclosure, the first TSV structure and the second TSV structure are respectively manufactured, and the first TSV structure and the second TSV structure are electrically connected at the first side of the substrate, which meet the electrical conductivity of the semiconductor structure to stack and interconnect with other semiconductor structures. The minimum sections of the first TSV structure and the second TSV structure in the radial direction are further provided at the first side of the substrate, which shortens the manufacturing lengths of the first TSV structure and the second TSV structure, reduces the sizes of the first TSV structure and the second TSV structure, increases a space of the semiconductor structure to integrate a semiconductor device, improves thermal performance of conductive metal when the TSV structure is formed, and makes the TSV structure more stable. Therefore, the present disclosure improves the level of integration in the semiconductor structure and taps the potential of the semiconductor structure toward miniaturization.

The embodiments or implementations of this specification are described in a progressive manner, and each embodiment focuses on differences from other embodiments. The same or similar parts between the embodiments may refer to each other.

In the description of this specification, the description with reference to terms such as “an embodiment”, “an exemplary embodiment”, “some implementations”, “a schematic implementation”, and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the accompanying drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one structure from another.

The same elements in one or more accompanying drawings are denoted by similar reference numerals. For the sake of clarity, various parts in the accompanying drawings are not drawn to scale. In addition, some well-known parts may not be shown. For the sake of brevity, a structure obtained by implementing a plurality of steps may be shown in one figure. In order to understand the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

According to the semiconductor structure and the forming method thereof provided by the embodiments of the present disclosure, a first TSV structure and a second TSV structure form a multi-segment structure penetrating through the semiconductor structure. The present disclosure shortens manufacturing lengths of the first TSV structure and the second TSV structure, reduces sizes of the first TSV structure and the second TSV structure, and makes the TSV structure more stable.

1. A semiconductor structure, comprising:
a substrate, comprising a first side and a second side opposite to each other;
a dielectric layer, provided at the first side of the substrate;
a first through silicon via (TSV) structure, extending from a top surface of the dielectric layer to the first side of the substrate; and
a second TSV structure, extending from the second side of the substrate to the first side of the substrate, coming into contact with the first TSV structure at the first side of the substrate, and having a preset opening width.

2. The semiconductor structure according to claim 1, wherein a metal liner is provided in the dielectric layer, and both the first TSV structure and the second TSV structure come into contact with the metal liner.

3. The semiconductor structure according to claim 2, wherein the first TSV structure defines a first pattern at a bottom surface of the dielectric layer, the second TSV structure defines a second pattern at the first side of the substrate, and projection of the first pattern on the substrate coincides with projection of the second pattern on the substrate.

4. The semiconductor structure according to claim 2, wherein an extension direction of the first TSV structure serves as a first direction, the first direction refers to an axial direction of the first TSV structure, and along the first direction, a radial size of the first TSV structure decreases gradually; and
an extension direction of the second TSV structure serves as a second direction opposite to the first direction, the second direction refers to an axial direction of the second TSV structure, and along the second direction, a radial size of the second TSV structure decreases gradually.

5. The semiconductor structure according to claim 4, the semiconductor structure further comprises:
a third TSV structure, extending from the second side of the substrate to the first side of the substrate, and connected to the metal liner.

6. The semiconductor structure according to claim 5, wherein the first TSV structure defines a first pattern at a bottom surface of the dielectric layer, and projection of the first pattern on the substrate falls within projection of the metal liner on the substrate; and
the second TSV structure defines a second pattern at the first side of the substrate, the third TSV structure defines a third pattern at the first side of the substrate, and projection of each of the second pattern and the third pattern on the substrate falls within the projection of the metal liner on the substrate.

7. The semiconductor structure according to claim 1, wherein the preset opening width ranges from 2 μm to 20 μm.

8. A forming method of a semiconductor structure, comprising:
providing a substrate and a dielectric layer disposed on the substrate, the substrate comprising a first side and a second side, and the dielectric layer being provided at the first side of the substrate;
forming a first through silicon via (TSV) structure, the first TSV structure extending from a top surface of the dielectric layer to the first side of the substrate; and
forming a second TSV structure, the second TSV structure extending from the second side of the substrate to the first side of the substrate, coming into contact with the first TSV structure at the first side of the substrate, and having a preset opening width.

9. The forming method of a semiconductor structure according to claim 8, wherein the forming a first TSV structure comprises:
forming a first opening, the first opening extending from the top surface of the dielectric layer to the first side of the substrate;
forming the first TSV structure, the first TSV structure covering the first opening; and
performing first annealing on the semiconductor structure.

10. The forming method of a semiconductor structure according to claim 9, wherein the forming a second TSV structure comprises:
forming a second opening, the second opening extending from the second side of the substrate to the first side of the substrate;
forming the second TSV structure, the second TSV structure covering the second opening; and
performing second annealing on the semiconductor structure.

11. The forming method of a semiconductor structure according to claim 10, the method further comprises:
etching back the second side of the substrate, thinning the substrate according to a length of the second TSV structure to be formed.

12. The forming method of a semiconductor structure according to claim 11, the method further comprises:
forming a metal liner, the metal liner being provided in the dielectric layer, wherein a first side of the metal liner covers a bottom surface of the first TSV structure, and a second side of the metal liner covers a bottom surface of the second TSV structure.

13. The forming method of a semiconductor structure according to claim 12, the method further comprises:
forming a third TSV structure, the third TSV structure extending from the second side of the substrate to the first side of the substrate, wherein the second side of the metal liner covers a bottom surface of the third TSV structure.

14. The forming method of a semiconductor structure according to claim 13, wherein the forming a third TSV structure comprises:
forming a third opening, the third opening extending from the second side of the substrate to the first side of the substrate, and exposing a part of the second side of the metal liner; and
forming the third TSV structure, the third TSV structure covering the third opening and the exposed second side of the metal liner.

15. The forming method of a semiconductor structure according to claim 14, wherein the forming a second TSV structure and the forming a third TSV structure are performed at the same time; and
after the second TSV structure and the third TSV structure are formed, the second annealing is performed on the semiconductor structure.
